(19) United States
(12) Patent Application Publication
(10) Pub. No.: US 2020/0139412 A1
(43) Pub. Date: May 7, 2020

(54) PLASMA GENERATING DEVICE AND PLASMA CLEANING DEVICE

(71) Applicant: Yongqing WANG, (US)

(72) Inventor: Yongqing WANG, (US)

(21) Appl. No.: 16/332,791

(22) PCT Filed: Dec. 15, 2018
(86) PCT No.: PCT/CN2018/121357

§ 371 Date: Mar. 13, 2019

(30) Foreign Application Priority Data
Oct. 30, 2018 (CN) 201811279845.3

(51) Int. Cl. B08B 7/00; H01J 37/32

(52) U.S. Cl. CPC B08B 7/0035; H01J 37/32449; H01J 37/32082

(57) ABSTRACT

The application provides a plasma generating device and a plasma cleaning device using the plasma generating device to clean a wait-treated surface. The plasma generating device includes at least one plasma nozzle assembly. The plasma nozzle assembly includes a plurality of plasma nozzles and a common channel.

### BACKGROUND OF THE INVENTION

### 1. Field of the Invention

The application relates to a technical field of display panels, and more particularly to a plasma generating device and a plasma cleaning device.

### 2. Description of the Prior Art

The plasma has the characteristics of low macroscopic temperature and high electron temperature. It is rich in high-activity excited ions and high-energy charged particles, so it is suitable for surface modification of materials and cleaning of glass and other objects.

FIG. 1 shows a traditional plasma generating device 1 in the prior art. Referring to FIG. 1, the plasma generating device 1 includes a gas source 11, a high voltage radio frequency generator 12 and a showerhead 13. The showerhead 13 has a chamber 131, which is an insulator. The gas of the gas source 11 passes through a gas path 111 to form a gas flow 112 in the chamber 131 of the showerhead 13. The high voltage radio frequency generator 12 can apply a radio frequency voltage to a cathode and a central electrode 121 in the showerhead 13 to generate a high frequency alternating electric field. And then, the gas flow 112 in the chamber 131 forms a plasma beam 2 under the action of an electric arc 122.

In a semiconductor industry and a display panel industry, the above plasma beam 2 is often used to clean products to increase their surface adhesion. For example, cleaning glass substrates, cleaning terminals before binding, and cleaning glass covers before lamination. The plasma beam can clean the product by physical bombardment to make a surface material of the cleaned product be changed into particles and gaseous substances, which are then discharged through being vacuumized, so as to achieve the purpose of cleaning.

FIG. 2 shows a traditional plasma cleaning device 3 in the prior art. Referring to FIG. 2, the plasma cleaning device 3 includes a plasma generating cylinder 31. One end of the plasma generating cylinder 31 is a gas inlet, and the other end thereof is a gas outlet. The gas inlet and the gas outlet are each provided with an annular electrode 32, which is electrically connected with an excitation power supply 33, thereby making the gas of the plasma generating cylinder 31 be the plasma. Moreover, the plasma generating cylinder 31 disposes multiple nozzles 311 with equidistant intervals thereon to eject the plasma beams for cleaning a wait-cleaned surface S.

### 3. Technical Problem

In the plasma cleaning device 3 shown in FIG. 2, because the plasma beams are generated in the plasma generating cylinder 31 and then ejected through the nozzles 311, the plasma beams cannot be ejected evenly. So it will result in uneven cleaning effects. Further, when needing to clean a curved surface, the plasma cleaning device 3 still has the problem of cleaning dead angles.

In view of this, it is necessary to provide a new plasma generating device to overcome the above shortcomings.

### BRIEF SUMMARY OF THE INVENTION

### Technical Solutions

The object of the application is to provide a plasma generating device, which has a modular structure and can be applied to a plasma cleaning device; and plasma generating device and the plasma cleaning device using the plasma generating device are especially suitable for cleaning curved covers, and can achieve a best cleaning uniformity by reasonably setting plasma nozzles.

To achieve the aforementioned object, a plasma generating device is provided for being used to process a surface to be treated. The plasma generating device includes at least one plasma nozzle assembly. The plasma nozzle assembly includes a plurality of plasma nozzles and a common channel; wherein each of the plasma nozzles having an outlet end and an inlet end;

each of the plasma nozzles is fluidly connected with the common channel through the inlet end, and the plasma nozzles are uniformly arranged on the common channel;

the outlet end of each of the plasma nozzles faces the surface to be treated, and distances between the outlet ends of the plasma nozzles and the surface to be treated are equal.

In one preferred embodiment, a plasma generating device is provided, including a plurality of plasma nozzle assemblies and a gas source. Each of the plasma nozzle assemblies includes a common channel and a plurality of plasma nozzles. Each of the plasma nozzles has an outlet end and an inlet end, and a diameter of the inlet end is larger than that of the outlet end. Each of the plasma nozzles is fluidly connected with the common channel through the inlet end, and the plasma nozzles are uniformly arranged on the common channel. The outlet end of each of the plasma nozzles faces the surface to be treated, and distances between the outlet ends of the plasma nozzles and the surface to be treated are equal. The common channels of the plasma nozzle assemblies are arranged in parallel; and the outlet ends of the plasma nozzles are arranged in staggered.

In one embodiment, the plasma generating device includes the gas source, which is fluidly connected with the common channel and is used to provide a gas for each of the plasma nozzle assemblies.

In one embodiment, the plasma generating device further includes an excitation power supply, which is electrically connected with the plasma nozzles and is used to excite the gas entering into the plasma nozzles from the inlet ends to be a plasma.

In one embodiment, the excitation power supply is a high voltage radio frequency generator.

In one embodiment, a diameter of the inlet end is larger than that of the outlet end.

In one embodiment, the plasma generating device includes a plurality of plasma nozzle assemblies, and the common channels of the plasma nozzle assemblies are arranged in parallel.

In one embodiment, the outlet ends of the plasma nozzles are arranged in staggered.

The application further provides a plasma cleaning device, including at least one plasma generating device and a platform. The platform is disposed under the plasma generating device and is used to carry a surface to be treated.

In one embodiment, the plasma cleaning device further includes a treatment chamber, and the surface to be treated can be cleaned by a plasma in the treatment chamber.

In one embodiment, the treatment chamber is connected with a vacuum exhaust device through at least one exhaust pipe for creating a vacuum environment.

### Beneficial Effect

According to the plasma generating device and the plasma cleaning device of the present application, the plasma generating device has a modular structure, whereby the plasma cleaning device using the plasma generating device is especially suitable for cleaning curved covers, and can achieve a best cleaning uniformity by reasonably setting plasma nozzles.

### BRIEF DESCRIPTION OF THE DRAWINGS

For more clearly illustrating the technical scheme in the embodiment of the present application, the following text will briefly introduce the accompanying drawings used in the preferred embodiment. It is obvious that the accompanying drawings in the following description are only some embodiments of the present application. For the technical personnel of the field, other drawings can also be obtained from these drawings without paying creative work.

FIG. 1 is a structure schematic view of a plasma generating device of the prior art;

FIG. 2 is a structure schematic view of a plasma cleaning device of the prior art;

FIG. 3 is a structure schematic view of a plasma generating device according to one embodiment of the present application; and

FIG. 4 is a structure schematic view of a plasma cleaning device according to one embodiment of the present application.

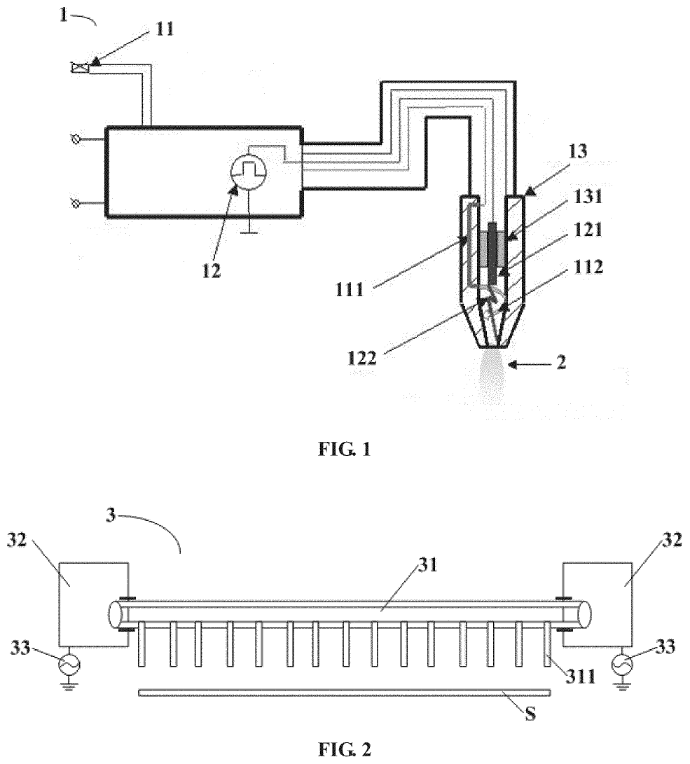

### DETAILED DESCRIPTION OF THE PREFERRED EMBODIMENTS

The following text will describe embodiments of the present invention in detailed. The embodiments are shown in the accompanying drawings, in which the same or similar signs represent the same or similar elements or elements with the same or similar functions from beginning to end. The following embodiments described with reference to the accompanying drawings are illustrative and are intended only to explain the present invention and are not understood as limitations to the invention.

In the present invention, unless expressly described otherwise, the meaning of a first feature located on a second feature or under the second feature can refer to a direct contact between the first and second features, or can refer to an indirect contact between the first and second features by other features. Moreover, the meaning of “above” includes “over” and “in the . . . inclined top”, or only represents that the level of the first feature is higher than the second feature. Further, the meaning of “below” includes “under” and “in the . . . oblique below”, or only represents that the level of the first feature is lower than the second feature.

The following disclosure provides many different embodiments or examples to implement different structures of the present invention. In order to simplify the description, only parts and settings in the specific examples are described in the following sections. Of course, they are only examples, and are not used to limit the invention. In addition, reference numbers and/or reference letters can be repeatedly used in different examples of the present invention for the purpose of simplification and clarity, and they do not represent the relationship of the various embodiments and/or elements discussed. In addition, the present invention provides examples of various specific processes and materials, but those of ordinary skill in the art can be aware of the application of other processes and/or the use of other materials.

In order to avoid being unable to clearly show a plasma generating device and a plasma cleaning device of this application due to unnecessary details, only main components related to this application are shown in the drawings. It will be understood by those skilled in the art that even if omitted in the drawings, the plasma generating device and the plasma cleaning device described herein also include other conventional structures such as a rack and a drive rack.

Please refer to FIG. 3, in this embodiment, a plasma generating device 100 is provided for processing a surface S to be treated. As shown in FIG. 3, the plasma generating device 100 includes at least one plasma nozzle assembly 110, a gas source 120 and an excitation power supply 130. Wherein, the plasma nozzle assembly 110 includes a plurality of plasma nozzles 111 and a common channel 112.

Referring to FIG. 3, each plasma nozzle 111 has an inlet end 1111 and an outlet end 1112. Preferably, a diameter of the inlet end 1111 is larger than that of the outlet end 1112. Each plasma nozzle 111 is fluidly connected with the common channel 112 through the inlet end 1111. The plasma nozzles 111 are uniformly arranged on the common channel 112, and the outlet end 1112 of each plasma nozzle 111 faces the surface S to be treated. Distances between the outlet ends 1112 of all the plasma nozzles 111 and the surface S to be treated are equal. For example, referring to FIG. 3, a gap D1 between a first plasma nozzle 111a and a second plasma nozzle 111b is equal to a gap D2 between the second plasma nozzle 111b and a third plasma nozzle 111c. Further, a distance L1 between the first plasma nozzle 111a and the wait-treated surface S is equal to a distance L2 between the second plasma nozzle 111b and the wait-treated surface S, and is also equal to a distance L3 between the third plasma nozzle 111c and the wait-treated surface S.

Moreover, referring to FIG. 3, the gas source 120 is fluidly connected with the common channel 112 to provide a gas for the plasma nozzle assembly 110. The excitation power supply 130 is electrically connected with the plasma nozzles 111 through internal conductors. That is, in the embodiment of the plasma generating device 100, the gas is uniformly conveyed to each of the plasma nozzles 111 through the common channel 112, and a radio frequency voltage is applied to the plasma nozzles 111 by the excitation power supply 130 to generate a high frequency alternating electric field in each plasma nozzle 111. Therefore, the gas in each plasma nozzle 111 is excited to be a plasma.

Of course, in order to more uniformly clean the surface S to be treated, the plasma generating device 100 may include a plurality of plasma nozzle assemblies 110. The common channel 112 of the plasma nozzle assemblies 110 can be arranged in parallel, and the outlet ends 1112 of the plasma nozzles 111 can be arranged in staggered. Of course, each plasma nozzle assembly 110 can share the gas source 120 and the excitation power supply 130.

Gases used to form the plasma may be conventional gases used to form plasma in the field. For example, the gases can be Ar, O2, N2, CDA, etc.

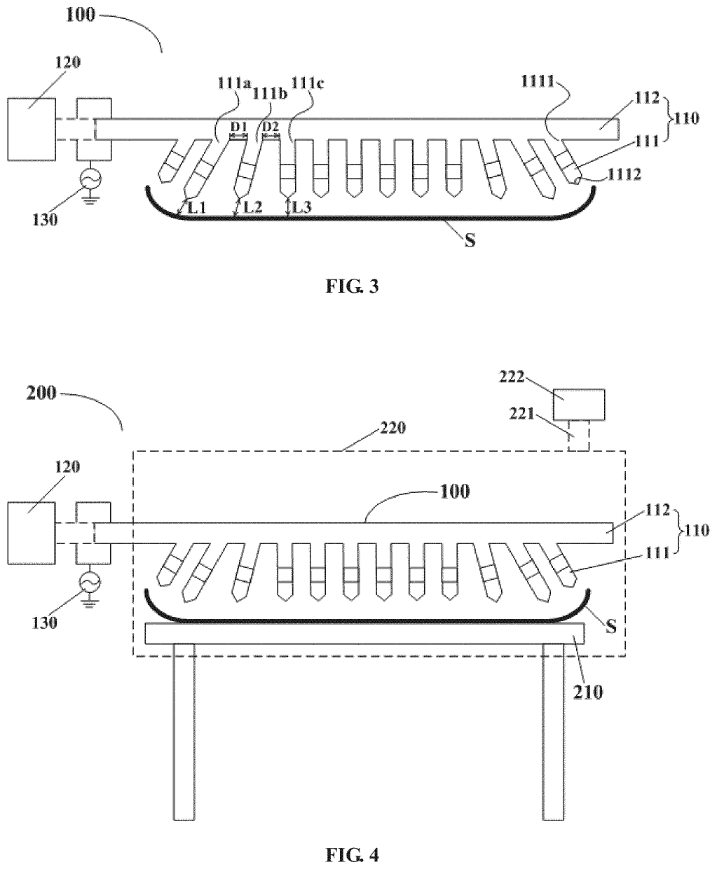

Please refer to FIG. 4, in the embodiment, the plasma cleaning device 200 is provided, including the plasma generating device 100 and a platform 210. The platform 210 is disposed under the plasma generating device 100 and is used to carry the wait-treated surface. Referring to FIG. 4, the plasma cleaning device 200 further includes a treatment chamber 220, which is connected with a vacuum exhaust device 222 through at least one exhaust pipe 221. Thus, a vacuum environment is created in the treatment chamber 220, and the surface S to be treated can be cleaned by the plasma in the treatment chamber. The treatment chamber 220, the exhaust pipe 221 and the vacuum exhaust device 222 can create the vacuum environment around the wait-treated surface S and the plasma nozzles 111 of the plasma generating device 100, and can discharge the exhaust gas and the particulate matter produced in the cleaning process by negative pressure suction.

According to the plasma generating device 100 and the plasma cleaning device 200 of this application, the plasma generating device has a modular structure, and the plasma cleaning device using the plasma generating device is especially suitable for cleaning a cover with a curved surface. Referring to FIGS. 3 and 4, the plasma nozzles 111 located in a horizontal section of the wait-cleaned surface S is perpendicular to the wait-cleaned surface S, so plasma beams emitted from the outlet ends 1112 at the horizontal cleaning position are perpendicular to the wait-cleaned surface S. In a bending section of the wait-cleaned surface S, the plasma nozzles 111 are inclined, so that plasma beams emitted from the outlet ends 1112 at the bending cleaning position are also almost perpendicular to the wait-cleaned surface S. Therefore, the plasma generating device 100 and the plasma cleaning device 200 of the present invention can achieve a best cleaning uniformity.

The present application has been described by the relevant embodiments described above, but the above embodiments are only examples of the implementation of the present application. It must be noted that the disclosed embodiments do not limit the scope of this application. On the contrary, the modifications and equalization settings included in the spirit and scope of the claims are within the scope of this application.

### INDUSTRIAL PRACTICABILITY

The subject of this application can be manufactured and used in industry and has industrial practicability.

What is claimed is:

1. A plasma generating device, being used to process a surface to be treated, wherein the plasma generating device including a plurality of plasma nozzle assemblies and a gas source, and wherein
each of the plasma nozzle assemblies including:
a common channel; and
a plurality of plasma nozzles, each of which has an outlet end and an inlet end, and a diameter of the inlet end being larger than that of the outlet end;
each of the plasma nozzles being fluidly connected with the common channel through the inlet end, and the plasma nozzles being uniformly arranged on the common channel;
the outlet end of each of the plasma nozzles facing the surface to be treated, and distances between the outlet ends of the plasma nozzles and the surface to be treated being equal;
the common channels of the plasma nozzle assemblies being arranged in parallel; and
the outlet ends of the plasma nozzles being arranged in staggered.

2. The plasma generating device as claimed in claim 1, characterized in that: the plasma generating device includes the gas source, which is fluidly connected with the common channel and is used to provide a gas for each of the plasma nozzle assemblies.

3. The plasma generating device as claimed in claim 2, characterized in that: the plasma generating device further includes an excitation power supply, which is electrically connected with the plasma nozzles and is used to excite the gas entering into the plasma nozzles from the inlet ends to be a plasma.

4. The plasma generating device as claimed in claim 3, characterized in that: the excitation power supply is a high voltage radio frequency generator.

5. A plasma generating device, being used to process a surface to be treated, wherein the plasma generating device including at least one plasma nozzle assembly, and the plasma nozzle assembly including a plurality of plasma nozzles and a common channel; wherein each of the plasma nozzles having an outlet end and an inlet end;
each of the plasma nozzles being fluidly connected with the common channel through the inlet end, and the plasma nozzles being uniformly arranged on the common channel;
the outlet end of each of the plasma nozzles facing the surface to be treated, and distances between the outlet ends of the plasma nozzles and the surface to be treated being equal.

6. The plasma generating device as claimed in claim 5, characterized in that: the plasma generating device includes a gas source, which is fluidly connected with the common channel and is used to provide a gas for the plasma nozzle assembly.

7. The plasma generating device as claimed in claim 6, characterized in that: the plasma generating device further includes an excitation power supply, which is electrically connected with the plasma nozzles and is used to excite the gas entering into the plasma nozzles from the inlet ends to be a plasma.

8. The plasma generating device as claimed in claim 7, characterized in that: the excitation power supply is a high voltage radio frequency generator.

9. The plasma generating device as claimed in claim 1, characterized in that: a diameter of the inlet end is larger than that of the outlet end.

10. The plasma generating device as claimed in claim 5, characterized in that: the plasma generating device includes a plurality of plasma nozzle assemblies, the common channels of the plasma nozzle assemblies are arranged in parallel.

11. The plasma generating device as claimed in claim 10, characterized in that: the outlet ends of the plasma nozzles are arranged in staggered.

12. A plasma cleaning device, including at least one plasma generating device as claimed in claim 1 and a platform, the platform being disposed under the plasma generating device and being used to carry a surface to be treated.

13. The plasma cleaning device as claimed in claim 12, characterized in that: the plasma cleaning device further includes a treatment chamber, and the surface to be treated can be cleaned by a plasma in the treatment chamber.

14. The plasma cleaning device as claimed in claim 13, characterized in that: the treatment chamber is connected with a vacuum exhaust device through at least one exhaust pipe for creating a vacuum environment.
